(19) United States
(12) Patent Application Publication
(10) Pub. No.: US 2022/0384681 A1
(43) Pub. Date: Dec. 1, 2022

(54) NITRIDE SEMICONDUCTOR LIGHT-EMITTING ELEMENT

(71) Applicant: NIKKISO CO., LTD., Tokyo (JP)

(72) Inventors: Yusuke MATSUKURA, Ishikawa (JP); Cyril PERNOT, Ishikawa (JP)

(73) Assignee: NIKKISO CO., LTD., Tokyo (JP)

(21) Appl. No.: 17/736,459

(22) Filed: May 4, 2022

(30) Foreign Application Priority Data
May 7, 2021 (JP) 2021-079000

(51) Int. Cl. H01L 33/32; H01L 33/40

(52) U.S. Cl. CPC H01L 33/32; H01L 33/405

(57) ABSTRACT

A nitride semiconductor light-emitting element includes a first semiconductor layer; an active layer provided on the first semiconductor layer on one side; a second semiconductor layer provided on the active layer on the opposite side to the first semiconductor layer so as to be in contact with the active layer; and a reflective electrode provided on the second semiconductor layer on the opposite side to the active layer so as to be in contact with the second semiconductor layer and reflects light emitted from the active layer. When an optical film thickness of the second semiconductor layer is an optical film thickness L [nm], a central wavelength of the light emitted from the active layer is a wavelength λ [nm], and an arbitrary number between 1 and 2 is a value m, a relationship 0.48 m λ≤L≤0.5 m λ+(−0.05 m+0.3)λ is satisfied.

### CROSS-REFERENCE TO RELATED APPLICATION

The present patent application claims the priority of Japanese patent application No. 2021/079000 filed on May 7, 2021, and the entire contents of Japanese patent application No. 2021/079000 are hereby incorporated by reference.

### TECHNICAL FIELD

The present invention relates to a nitride semiconductor light-emitting element.

### BACKGROUND ART

Patent Literature 1 discloses a nitride semiconductor light-emitting element configured such that deep ultraviolet light generated by an active layer is extracted from a substrate side. This nitride semiconductor light-emitting element includes an n-type semiconductor layer, an active layer, a p-type AlGaN electron blocking layer, a p-type contact layer and a p-side reflective electrode in this order on the substrate.

The p-side reflective electrode is an electrode that has a property of reflecting deep ultraviolet light. Since the p-side reflective electrode is provided in the nitride semiconductor light-emitting element, deep ultraviolet light emitted from the active layer toward the opposite side to the substrate is reflected at the p-side reflective electrode back toward the substrate and output of light extracted through the substrate is thereby improved.

### CITATION LIST

### Patent Literature

Patent Literature 1: JP 2020/098908 A

### SUMMARY OF INVENTION

In case of the nitride semiconductor light-emitting element described in Patent Literature 1, however, there is room for improvement in terms of further improving light output.

The invention was made in view of such circumstances and it is an object of the invention to provide a nitride semiconductor light-emitting element capable of improving light output.

To achieve the object described above, the invention provides a nitride semiconductor light-emitting element, comprising:
a first semiconductor layer;
an active layer provided on the first semiconductor layer on one side;
a second semiconductor layer provided on the active layer on the opposite side to the first semiconductor layer so as to be in contact with the active layer; and
a reflective electrode provided on the second semiconductor layer on the opposite side to the active layer so as to be in contact with the second semiconductor layer and reflects light emitted from the active layer,
wherein, when an optical film thickness of the second semiconductor layer is an optical film thickness L [nm], a central wavelength of the light emitted from the active layer is a wavelength λ [nm], and an arbitrary number between 1 and 2 is a value m, a relationship 0.48 m λ≤L≤0.5 m λ+(−0.05 m+0.3)λ is satisfied.

### Advantageous Effects of Invention

According to the invention, it is possible to provide a nitride semiconductor light-emitting element capable of improving light output.

### BRIEF DESCRIPTION OF DRAWINGS

FIG. 1 is a schematic diagram illustrating a configuration of a nitride semiconductor light-emitting element in an embodiment.

FIG. 2 is a graph showing a relationship between an optical film thickness of a second semiconductor layer and initial light output and between the optical film thickness and residual light output in Example 1.

FIG. 3 is a graph showing a relationship between the optical film thickness of the second semiconductor layer and forward voltage in Example 2.

### DESCRIPTION OF EMBODIMENTS

### Embodiment

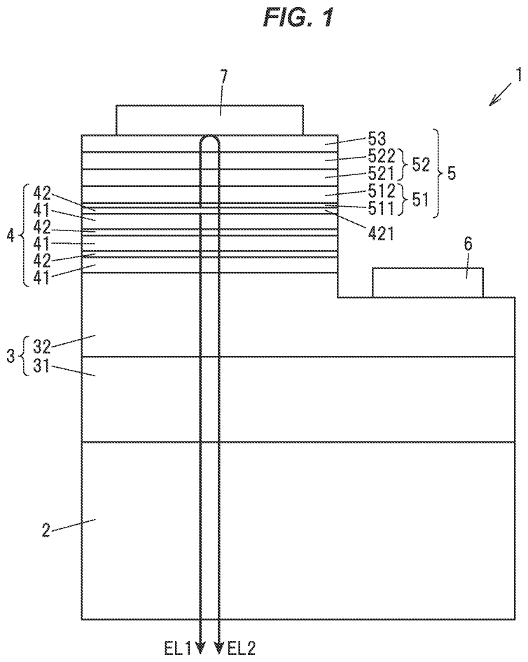

An embodiment of the invention will be described in reference to the FIGS. 1 to 3. The embodiment below is described as a preferred illustrative example for implementing the invention. Although some part of the embodiment specifically illustrates various technically preferable matters, the technical scope of the invention is not limited to such specific aspects. In addition, a scale ratio of each constituent element in each drawing is not necessarily the same as the actual scale ratio of the nitride semiconductor light-emitting element.

(Nitride Semiconductor Light-Emitting Element 1)

FIG. 1 is a schematic diagram illustrating a configuration of a nitride semiconductor light-emitting element 1 in the present embodiment. The nitride semiconductor light-emitting element 1 (hereinafter, also simply referred to as “light-emitting element 1”) can constitute, e.g., a light-emitting diode (LED) or a semiconductor laser (LD: laser diode). In the present embodiment, the light-emitting element 1 is a light-emitting diode (LED) that emits light with a wavelength in an ultraviolet region. Particularly, the light-emitting element 1 in the present embodiment emits deep ultraviolet light at a central wavelength of not less than 200 nm not more than 365 nm. The light-emitting element 1 in the present embodiment can be used in fields such as, e.g., sterilization (e.g., air purification, water purification, etc.), medical treatment (e.g., light therapy, measurement/analysis, etc.), UV curing, etc.

The light-emitting element 1 includes a first semiconductor layer 3, an active layer 4 and a second semiconductor layer 5 in this order on a substrate 2. The light-emitting element 1 also includes an n-side electrode 6 provided on the first semiconductor layer 3, and a p-side reflective electrode 7 provided on the second semiconductor layer 5. Hereinafter for convenience, a direction of stacking the substrate 2, the first semiconductor layer 3, the active layer 4 and the second semiconductor layer 5 (an up-and-down direction in FIG. 1) is referred to as the up-and-down direction, one side of the substrate 2 where the first semiconductor layer 3, the active layer 4 and the second semiconductor layer 5 are stacked (i.e., an upper side in FIG. 1) is referred to as the upper side, and the opposite side (i.e., a lower side in FIG. 1) is referred to as the lower side. The terms “upper” and “lower” are used for descriptive purposes and do not limit the posture of the light-emitting element 1 with respect to the vertical direction when, e.g., the light-emitting element 1 is in use. In the present embodiment, each layer constituting the light-emitting element 1 has a thickness in the up-and-down direction.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). Some of these group III elements may be substituted with boron (B) or thallium (Tl), etc. In addition, nitrogen (N) may be partially substituted with phosphorus (P), arsenic (As), antimony (Sb) or bismuth (Bi), etc. Next, each constituent element of the light-emitting element 1 will be described.

(Substrate 2)

The substrate 2 is made of a material transparent to light (deep ultraviolet light in the present embodiment) emitted by the active layer 4. The substrate 2 is, e.g., a sapphire (Al₂O₃) substrate. A growth surface of the substrate 2 (i.e., un upper surface of the substrate 2) is a c-plane. The growth surface of the substrate 2 may have an off angle with respect to the c-plane. Alternatively, e.g., an aluminum nitride (AlN) substrate or an aluminum gallium nitride (AlGaN) substrate, etc., may be used as the substrate 2. Here, “AlGaN” is a ternary mixed crystal in which a ratio of a composition of group III elements (i.e., a total composition of aluminum (Al) and gallium (Ga)) to a composition of nitrogen (N) is 1:1, and an aluminum composition ratio and a gallium composition ratio are arbitrary.

(First Semiconductor Layer 3)

The first semiconductor layer 3 is a semiconductor layer formed between the substrate 2 and the active layer 4. In the present embodiment, the first semiconductor layer 3 has a buffer layer 31 and an n-type cladding layer 32.

The buffer layer 31 is formed on the substrate 2. In the present embodiment, the buffer layer 31 is made of aluminum nitride. Alternatively, the buffer layer 31 may be composed of an aluminum nitride layer formed on the substrate 2 and an undoped aluminum gallium nitride layer formed on the aluminum nitride layer. When the substrate 2 is an aluminum nitride substrate or an aluminum gallium nitride substrate, the buffer layer 31 may not be necessarily included.

The n-type cladding layer 32 is formed on the buffer layer 31. The n-type cladding layer 32 is made of, e.g., Al_{q}Ga_{1-q}N (0≤q≤1) doped with silicon (Si) as an n-type impurity. The subscript q in the composition Al_{q}Ga_{1-q}N indicates an Al composition ratio (also called MN mole fraction). In the present embodiment, the n-type cladding layer is made of n-type AlGaN (i.e., 0<q<1 is satisfied). Alternatively, germanium (Ge), selenium (Se) or tellurium (Te), etc., may be used as the n-type impurity. The n-type cladding layer 32 has a film thickness of not less than 1 μm and not more than 4 μm, and can be, e.g., about 2 μm in film thickness. The n-type cladding layer 32 may have a single layer structure or may have a multilayer structure.

(Active Layer 4)

The active layer 4 is formed on the n-type cladding layer 32. The active layer 4 has a multiple quantum well structure that includes plural well layers 42 and is formed by alternately stacking barrier layers 41 and the well layers 42. In the present embodiment, the active layer 4 has three barrier layers 41 and three well layers 42 which are arranged such that the barrier layer 41 is located at the bottom and the well layer 42 at the top. Each barrier layer 41 is made of AlᵣGa₁₋ᵣN (0<r≤1). Each well layer 42 is made of AlₛGa₁₋ₛN (0≤s<1). An Al composition ratio r of each barrier layer 41 is higher than an Al composition ratio s of each well layer 42 (i.e., r>s is satisfied).

The active layer 4 generates light at a predetermined wavelength by recombination of electrons with holes in the multiple quantum well structure. In the present embodiment, the active layer 4 is configured to have a band gap of not less than 3.4 eV so that deep ultraviolet light at a wavelength of not more than 365 nm can be output. Particularly in the present embodiment, the active layer 4 is configured so that deep ultraviolet light at a central wavelength of not less than 200 nm and not more than 365 nm can be generated. The central wavelength of light emitted from the active layer 4 is preferably not less than 240 nm and not more than 365 nm, further preferably, not less than 260 nm and not more than 365 nm. When the active layer 4 is made of AlGaN and an emission wavelength is short (i.e., the Al composition ratio of the active layer 4 is high), light emission can be stronger in an a-axis or m-axis direction than in a c-axis direction. Therefore, when the emission wavelength is longer than a certain value (i.e., when the Al composition ratio of the active layer 4 is lower than a certain value), light traveling from the active layer 4 in the c-axis direction is stronger, hence, it is easier to improve light output through the substrate 2. In this regard, the numbers of the barrier layers 41 and the well layers 42 are not limited to three each, and may be two each or not less than four each. In addition, the active layer 4 may be configured to have a single quantum well structure having one well layer 42.

Hereinafter, among the three well layers 42, the well layer 42 adjacent to the second semiconductor layer 5 is referred to as a top well layer 421. Each of the three well layers 42 emits light when the light-emitting element 1 is energized, but the top well layer 421 tends to emit light most strongly.

(Second Semiconductor Layer 5)

The second semiconductor layer 5 is formed in contact with the top well layer 421 of the active layer 4 on the upper side of the top well layer 421. The second semiconductor layer 5 is a layer including at least a p-type semiconductor layer (in the present embodiment, a second electron blocking layer 512, a p-type cladding layer 52 and a p-type contact layer 53 which are described later). It is preferable that the entire second semiconductor layer 5 have a transmittance of not less than 50% at the central wavelength of deep ultraviolet light emitted by the active layer 4. In the present embodiment, the second semiconductor layer 5 has a stacked structure in which an electron blocking layer 51, the p-type cladding layer 52 and the p-type contact layer 53 are stacked in this order from the lower side.

The electron blocking layer 51 serves to improve efficiency of electron injection into the active layer 4 by suppressing occurrence of the overflow phenomenon in which electrons leak from the active layer 4 to the p-type cladding layer 52 side. The electron blocking layer 51 has a stacked structure in which a first electron blocking layer 511 and the second electron blocking layer 512 are stacked in this order from the lower side.

The first electron blocking layer 511 is provided so as to be in contact with the top well layer 421 of the active layer 4. The first electron blocking layer 511 is made of, e.g., undoped AlᵣGa₁₋ₜN (0<t≤1). The first electron blocking layer 511 preferably has an Al composition ratio t of not less than 80% and is made of aluminum nitride (i.e., t=1) in the present embodiment. The higher the Al composition ratio, the higher the electron blocking effect of suppressing the passage of electrons. By forming the first electron blocking layer 511 with a high Al composition ratio at a position adjacent to the active layer 4, a high electron blocking effect is obtained at a position close to the active layer 4 and this makes it easy to ensure high electron existence probability in the three well layers 42. Although the first electron blocking layer 511 is an undoped layer in the present embodiment, it is not limited thereto. The first electron blocking layer 511 may be a layer containing an n-type impurity, a layer containing a p-type impurity, or a layer containing both an n-type impurity and a p-type impurity. In such cases, the impurity/impurities in the first electron blocking layer 511 may be contained in the entire first electron blocking layer 511 or may be contained in a part of the first electron blocking layer 511.

Here, if a film thickness of the first electron blocking layer 511 with a high Al composition is increased excessively, there is concern that an electrical resistance value of the entire light-emitting element 1 becomes excessively large. For this reason, the film thickness of the first electron blocking layer 511 is preferably not less than 1 nm and not more than 10 nm, more preferably, not less than 1 nm and not more than 5 nm. On the other hand, if the film thickness of the first electron blocking layer 511 is reduced, it increases the probability that electrons pass through the first electron blocking layer 511 from the lower side to the upper side due to the tunnel effect. Therefore, in the light-emitting element 1 of the present embodiment, the second electron blocking layer 512 is formed on the first electron blocking layer 511 and electrons passing through the first electron blocking layer 511 are blocked by the second electron blocking layer 512.

The second electron blocking layer 512 has a lower Al composition ratio than that of the first electron blocking layer 511. The second electron blocking layer 512 is made of, e.g., AlᵤGa₁₋ᵤN (0<u<1) doped with magnesium (Mg) as a p-type impurity. An Al composition ratio u of the second electron blocking layer 512 is preferably lower than the Al composition ratio of the first electron blocking layer 511 and is preferably, e.g., not less than 40% and not more than 90%. Meanwhile, a film thickness of the second electron blocking layer 512 is preferably not less than 1 nm and not more than 100 nm from the viewpoint of ensuring the sufficient electron blocking effect and also reducing the electrical resistance value. The film thickness of the second electron blocking layer 512 is also preferably not less than the film thickness of the first electron blocking layer 511. Zinc (Zn), beryllium (Be), calcium (Ca), strontium (Sr), barium (Ba) or carbon (C), etc., may be alternatively used as the p-type impurity. Although the second electron blocking layer 512 is a layer containing a p-type impurity in the present embodiment, it is not limited thereto. The second electron blocking layer 512 may be an undoped layer, a layer containing an n-type impurity, or a layer containing both an n-type impurity and a p-type impurity. The impurity/impurities in the second electron blocking layer 512 may be contained in the entire second electron blocking layer 512 or may be contained in a part of the second electron blocking layer 512. The electron blocking layer 51 may alternatively have a single layer structure.

The p-type cladding layer 52 is formed on the second electron blocking layer 512. The p-type cladding layer 52 has a stacked structure in which a first p-type cladding layer 521 and a second p-type cladding layer 522 are stacked in this order from the lower side.

The first p-type cladding layer 521 is made of, e.g., AlᵥGa₁₋ᵥN (0≤u<1) doped with magnesium as a p-type impurity. An Al composition ratio v is preferably not more than 70%.

The second p-type cladding layer 522 is a composition gradient layer in which Al composition ratio distribution in the up-and-down direction has a gradient such that the Al composition ratio decreases toward the upper side. The second p-type cladding layer 522 is made of, e.g., aluminum gallium nitride doped with magnesium as a p-type impurity. When the Al composition ratio of a lower portion of the second p-type cladding layer 522 is defined as an Al composition ratio w and the Al composition ratio of an upper portion thereof is defined as an Al composition ratio x, the Al composition ratios w, x and the Al composition ratio v of the first p-type cladding layer 521 satisfy the relationship x<w≤v. The Al composition ratio w of the second p-type cladding layer 522, which is the Al composition ratio of an end portion on the first p-type cladding layer 521 side, is preferably substantially equal to the Al composition ratio v of the first p-type cladding layer 521. In addition, each of the Al composition ratios w and v is preferably less than the Al composition ratio u of the second electron blocking layer 512. A film thickness of the second p-type cladding layer 522 is preferably not more than 10 nm. The film thickness of the second p-type cladding layer 522 is also preferably not more than the film thickness of the first p-type cladding layer 521.

In the light-emitting element 1 of the present embodiment, a sudden change in the Al composition ratio between the p-type contact layer 53 and the first p-type cladding layer 521, which are adjacent to the second p-type cladding layer 522 on the upper and lower sides, is suppressed by providing the second p-type cladding layer 522 as the composition gradient layer. As a result, occurrence of dislocations caused by lattice mismatch can be suppressed. When such dislocations occur, the rate of non-luminescent recombination between electrons and holes in the active later 4 increases and the light emitted from the active layer 4 may decrease. For this reason, the light-emitting element 1 preferably includes the second p-type cladding layer 522 as the composition gradient layer from the viewpoint of ensuring that sufficient light output is obtained. The p-type cladding layer 52 may alternatively have a single layer structure.

The p-type contact layer 53 is formed on the second p-type cladding layer 522. The p-type contact layer 53 is a p-type semiconductor layer in ohmic contact with the p-side reflective electrode 7 and is made of, e.g., p-type Al_{y}Ga_{1-y}N (0≤y<1) doped with a high concentration of a p-type impurity such as magnesium. An Al composition ratio y of the p-type contact layer 53 is not more than the Al composition ratio x of the end portion of the second p-type cladding layer 522 on the p-type contact layer 53 side, and is preferably not more than 40%. In the present embodiment, the p-type contact layer 53 has the Al composition ratio y of 0% and is made of p-type GaN.

A film thickness of the p-type contact layer 53 is preferably not more than 200 nm. When the p-type contact layer 53 is made of p-type GaN as in the present embodiment, the p-type contact layer 53 is a layer that absorbs deep ultraviolet light. Thus, in the present embodiment, the thickness of the p-type contact layer 53 is more preferably not more than 30 nm to reduce absorption of deep ultraviolet light by the p-type contact layer 53. Hereinafter, the film thickness of the first electron blocking layer 511 is defined as t1, the film thickness of the second electron blocking layer 512 as t2, the film thickness of the first p-type cladding layer 521 as t3, the film thickness of the second p-type cladding layer 522 as t4, and the film thickness of the p-type contact layer 53 as t5. It is preferable that the film thicknesses t1, t2, t4, t5 satisfy the relationship t1≤t4≤t5≤t2.

Here, an optical film thickness of the second semiconductor layer 5 is defined as an optical film thickness L [nm]. The optical film thickness L of the second semiconductor layer 5 is an optical distance in the up-and-down direction between the upper end and lower end of the second semiconductor layer 5. Hereinafter, when simply referring to “film thickness”, not “optical film thickness”, it means an actual film thickness (i.e., a physical film thickness). An optical film thickness of a semiconductor layer is obtained by multiplying a film thickness of the semiconductor layer by a refractive index of the semiconductor layer. In the present embodiment, the optical film thickness L of the second semiconductor layer 5 is expressed by L=(t1×n1)+(t2×n2)+(t3×n3)+(t4×n4) 30 (t5×n5), where n1 is a refractive index of the first electron blocking layer 511, n2 is a refractive index of the second electron blocking layer 512, n3 is a refractive index of the first p-type cladding layer 521, n4 is a refractive index of the second p-type cladding layer 522, and n5 is a refractive index of the p-type contact layer 53. The refractive index of each layer is a value corresponding to the Al composition ratio of each layer. In this regard, the refractive index of a semiconductor layer changes with the Al composition ratio of the semiconductor layer. For the second p-type cladding layer 522 in which the Al composition ratio changes in the up-and-down direction, the refractive index n4 may be calculated as an average of the refractive index n3 of the first p-type cladding layer 521 adjacent to the second p-type cladding layer 522 on the lower side and the refractive index n5 of the p-type contact layer 53 adjacent to the second p-type cladding layer 522 on the upper side (i.e., (n3+n5)/2). In addition, in the present embodiment, when simply referring to “refractive index”, it means the refractive index at the central wavelength of the deep ultraviolet light emitted from the active layer 4, unless otherwise specified.

When the central wavelength of the light emitted from the active layer 4 is a wavelength λ [nm] and an arbitrary number is a value m (m=1 or m=2), the optical film thickness L, the wavelength λ [nm] and the value m satisfy a relationship 0.48 m λ≤L≤0.5 m λ+−0.05 m+0.3)λ. That is, the relationship 0.48 λ<L<0.75 λ is satisfied when m=1, and the relationship 0.96 λ≤L≤1.20 λ is satisfied when m=2. The possible range of the optical film thickness L when m=1 is 0.75 λ−0.48 λ=0.27 λ, and the possible range of the optical film thickness L when m=2 is 1.20 λ−0.96 λ=0.24 λ. When m=1, the optical film thickness L is preferably not less than 0.55 λ [nm] and not more than 0.70 λ [nm]. Meanwhile, when m=2, the optical film thickness L is preferably not less than 1.02 λ [nm] and not more than 1.15 λ [nm]. These preferable ranges of the optical film thickness L are supported by Experimental Example 1 (described later).

Although the second semiconductor layer 5 has the electron blocking layer 51, the p-type cladding layer 52 and the p-type contact layer 53 in the present embodiment, it is not limited thereto. The second semiconductor layer 5 can be composed of, e.g., only the electron blocking layer and the p-type contact layer. Alternatively, the second semiconductor layer 5 can be composed of only the p-type cladding layer and the p-type contact layer. Furthermore, the second semiconductor layer 5 can be composed of only the p-type contact layer.

(P-Side Reflective Electrode 7)

The p-side reflective electrode 7 is formed on the p-type contact layer 53. The p-side reflective electrode 7 is a reflective electrode that reflects the deep ultraviolet light emitted from the active later 4. The p-side reflective electrode 7 has a reflectance of not less than 50%, preferably not less than 60%, at the central wavelength of the light emitted by the active later 4. The p-side reflective electrode 7 is preferably a metal containing rhodium (Rh). The metal containing rhodium is highly reflective of deep ultraviolet light and is also highly bondable to the p-type contact layer 53. In the present embodiment, the p-side reflective electrode 7 is composed of a rhodium monolayer. The light emitted upward from the active layer 4 is reflected at an interface between the p-side reflective electrode 7 and the second semiconductor layer 5.

(N-Side Electrode 6)

The n-side electrode 6 is formed on the n-type cladding layer 32. It is preferable that the n-side electrode 6 have a reflectance of not less than 50% at the central wavelength of the deep ultraviolet light emitted by the active layer 4. The n-side electrode 6 can be made of, e.g., a multilayered film formed by sequentially stacking titanium (Ti), aluminum, titanium and gold (Au) on the n-type cladding layer 32. Light output of the light-emitting element 1 can be improved by using an electrode likely to reflect the light emitted from the active layer 4 as the n-side electrode 6. For example, deep ultraviolet light traveling in a direction diagonal to the up-and-down direction is sometimes reflected between the lower end portion of the substrate 2 and an air layer, etc., but such reflected light is reflected again at the n-side electrode 6 and more light can thereby be extracted through the substrate 2. However, the n-side electrode 6 is not limited thereto and may have a reflectance of less than 50% at the central wavelength of the deep ultraviolet light emitted by the active later 4.

The light-emitting element 1 in the present embodiment is a co-called flip-chip type light-emitting element configured such that each of the p-side reflective electrode 7 and the n-side electrode 6 is electrically connected to a mounting substrate (not shown) using gold (Au) bumps, etc., and light is extracted on the substrate 2 side. However, it is not limited thereto and the light-emitting element can be a vertical light-emitting element. The vertical light-emitting element is a light-emitting element in which an active layer is sandwiched between a p-side electrode and an n-side electrode. As an example of the vertical light-emitting element, it is possible to adopt a configuration in which the n-side electrode is made of a material unlikely to reflect light emitted from the active layer and the light emitted from the active layer is extracted on the n-side electrode side. As another example of the vertical light-emitting element, it is possible to adopt a configuration in which a reflective electrode reflecting the light emitted from the active layer is provided as the n-side electrode, an electrode unlikely to reflect the light emitted from the active layer is provided as the p-side electrode and light is extracted on the p-side electrode side. In this example, a second semiconductor layer, which is a semiconductor layer provided between the n-side electrode as the reflective electrode and the active layer, is a layer including an n-type semiconductor layer, and a first semiconductor layer provided on the active layer on the opposite side to the second semiconductor layer is a layer including a p-type semiconductor. In addition, in this example, it is designed such that an optical film thickness of the second semiconductor layer including the n-type semiconductor layer falls within the numerical value ranges described above. In this regard, when the light-emitting element is of the vertical type, the substrate and the buffer layer are preferably removed by laser lift-off, etc.

(Interference between Direct emission light EL1 and Reflected emission light EL2) Of the light emitted from the active layer 4, light emitted downward from the active layer 4 and directly extracted through the substrate 2 is referred to as direct emission light ELL and light emitted upward from the active layer 4, reflected at the p-side reflective electrode 7 and then extracted through the substrate 2 is referred to as reflected emission light EL2. In FIG. 1, respective examples of the direct emission light EL1 and the reflected emission light EL2 are schematically indicated by arrows. In fact, the deep ultraviolet light from the active layer 4 is emitted in all directions, but FIG. 1 schematically shows only the direct emission light EL1 emitted directly downward from the active layer 4 and the reflected emission light EL2 emitted directly upward from the active layer 4. In addition, since the top well layer 421 emits light most strongly among the three well layers 42 of the active layer 4 as described above, the top well layer 421 is shown as the source of the direct emission light EL1 and the reflected emission light EL2 in FIG. 1 for convenience of description.

The reflected emission light EL2 is emitted from the active layer 4, propagates from the lower end to the upper end of the second semiconductor layer 5, is reflected at the interface between the second semiconductor layer 5 and the p-side reflective electrode 7, propagates from the upper end to the lower end of the second semiconductor layer 5, and then interferes with the direct emission light ELL That is, the second semiconductor layer 5 is a layer in which the reflected emission light EL2 travels up and down before interfering with the direct emission light ELL Thus, the optical film thickness of the second semiconductor layer 5 has a direct relation with an optical path difference between the reflected emission light EL2 and the direct emission light EL1, and the direct emission light EL1 and the reflected emission light EL2 interfere with one another to strengthen each other or to weaken each other depending on a value of the optical film thickness of the second semiconductor layer 5.

The deep ultraviolet light is emitted from the active layer 4 in all directions, as described above. Therefore, in the light-emitting element 1, not only the direct emission light EL1 emitted straight down from the active layer 4 and the reflected emission light EL2 emitted straight up from the active layer 4 but also direct emission light emitted diagonally downward from the active layer 4 and reflected emission light emitted diagonally upward from the active layer 4 all interfere with one another.

### Experimental Example 1

In this experimental example, an experiment was conducted to evaluate initial light outputs and residual light outputs of samples 1 to 18 which are the light-emitting elements 1 provided with the second semiconductor layers 5 having various different optical film thicknesses.

The samples 1 to 18 have the same configuration as each other except for the optical film thickness L of the second semiconductor layer 5. Each of the samples 1 to 18 has the same configuration as the light-emitting element 1 described above. The samples 1 to 18 have the first p-type cladding layers 521 with different film thicknesses and thereby have different optical film thicknesses L. The film thickness of the first p-type cladding layer 521 of each sample and the optical film thickness L of each sample are shown in Table 1 described later.

In this experimental example, initial light output of each of samples 1 to 18 and residual light output of each of samples 1, 4, 9, 14, 17 were measured. The initial light output of each sample is light output when supplying a current of 350 mW to each sample immediately after being manufactured. Meanwhile, the residual light output is light output of each sample after continuously passing a current of 350 mW for 1000 hours. The initial light output and the residual light output were measured by a photodetector placed under each of the samples 1 to 18. Table 1 below shows the film thickness of each layer (i.e., the first electron blocking layer 511, the second electron blocking layer 512, the first p-type cladding layer 521, the second p-type cladding layer 522 and the p-type contact layer 53) constituting the second semiconductor layer 5 of each sample, the central wavelength of light emitted by each sample, the optical film thickness L of the second semiconductor layer 5 of each sample, and the initial light output and residual light output of each sample.

TABLE 1

| | | | | | | | Optical | | |
|---|---|---|---|---|---|---|---|---|---|
| | Film | Film | Film | Film | Film | | film | | |
| | thickness | thickness | thickness | thickness | thickness | | thickness | | |
| | of First | of Second | of First | of Second | of | Central | L of | | |
| | electron | electron | p-type | p-type | p-type | wave- | Second | Initial | Residual |
| | blocking | blocking | cladding | cladding | contact | length | semi- | light | light |
| | layer | layer | layer | layer | layer | λ | conductor | output | output |
| Sample | [nm] | [nm] | [nm] | [nm] | [nm] | [nm] | layer [nm] | [mW] | [mW] |
| 1 | 2 | 20 | 6 | 3 | 21 | 278.1 | 0.46λ | 87.2 | 42.7 |
| 2 | 2 | 20 | 12 | 3 | 21 | 279.7 | 0.51λ | 114.1 | — |
| 3 | 2 | 20 | 18 | 3 | 21 | 278.2 | 0.57λ | 131.5 | — |
| 4 | 2 | 20 | 24 | 3 | 21 | 278.0 | 0.62λ | 131.6 | 51.0 |
| 5 | 2 | 20 | 30 | 3 | 21 | 278.0 | 0.67λ | 128.8 | — |
| 6 | 2 | 20 | 36 | 3 | 21 | 279.5 | 0.72λ | 112.6 | — |
| 7 | 2 | 20 | 42 | 3 | 21 | 279.7 | 0.77λ | 95.6 | — |
| 8 | 2 | 20 | 48 | 3 | 21 | 279.7 | 0.83λ | 84.6 | — |
| 9 | 2 | 20 | 54 | 3 | 21 | 278.0 | 0.88λ | 83.4 | 41.2 |
| 10 | 2 | 20 | 60 | 3 | 21 | 277.8 | 0.94λ | 88.3 | — |
| 11 | 2 | 20 | 66 | 3 | 21 | 278.1 | 0.99λ | 102.3 | — |
| 12 | 2 | 20 | 69 | 3 | 21 | 279.4 | 1.01λ | 108.4 | — |
| 13 | 2 | 20 | 72 | 3 | 21 | 280.0 | 1.03λ | 114.4 | — |
| 14 | 2 | 20 | 78 | 3 | 21 | 279.8 | 1.09λ | 115.5 | 61.8 |
| 15 | 2 | 20 | 84 | 3 | 21 | 280.6 | 1.14λ | 114.3 | — |
| 16 | 2 | 20 | 90 | 3 | 21 | 280.7 | 1.19λ | 106.3 | — |
| 17 | 2 | 20 | 96 | 3 | 21 | 279.3 | 1.25λ | 92.6 | 39.0 |
| 18 | 2 | 20 | 102 | 3 | 21 | 278.8 | 1.30λ | 92.7 | — |

The film thickness of each layer of each sample shown in Table 1 was measured by a transmission electron microscope. The optical film thickness L of the second semiconductor layer 5 in Table 1 was calculated based on the respective film thicknesses and respective refractive indices of the first electron blocking layer 511, the second electron blocking layer 512, the first p-type cladding layer 521, the second p-type cladding layer 522 and the p-type contact layer 53. The refractive index of each layer of the second semiconductor layer 5 at the emission wavelength is determined based on the Al composition ratio of each layer, and for each of the samples 1 to 18, the Al composition ratio of the first electron blocking layer 511 was substantially 100%, the Al composition ratio of the second electron blocking layer 512 was substantially 80%, the Al composition ratio of the first p-type cladding layer 521 was substantially 55%, the Al composition ratio of the lower end of the second p-type cladding layer 522 was substantially the same as the Al composition ratio of the first p-type cladding layer 521 (i.e., substantially 55%), the Al composition ratio of the upper end of the second p-type cladding layer 522 was substantially the same as the Al composition ratio of the p-type contact layer 53 (i.e., substantially 0%), and the Al composition ratio of the p-type contact layer 53 was substantially 0%. Based on this, the optical film thickness L of the second semiconductor layer 5 was calculated on the assumption that the refractive index of the first electron blocking layer 511 is 2.30 which is a refractive index of AlN, the refractive index of the second electron blocking layer 512 is 2.38 which is a refractive index of Al_{0.8}Ga_{0.2}N, the refractive index of the first p-type cladding layer 521 is 2.44 which is a refractive index of Al_{0.55}Ga_{0.45}N, the refractive index of the second p-type cladding layer 522 is 2.52 which is an average of the refractive index of the first p-type cladding layer 521 and the refractive index of the p-type contact layer 53 (described next), and the refractive index of the p-type contact layer 53 is 2.60 which is a refractive index of GaN. The refractive index of each layer of the second semiconductor layer 5 is a refractive index of light with a wavelength of 280 nm. In Table 1, the optical film thickness L of each sample is expressed using the central wavelength 2 of the light output from each sample. This makes it easy to understand how many times thicker is the optical film thickness L of the second semiconductor layer 5 of each sample compared to the central wavelength 2 of the light output from each sample.

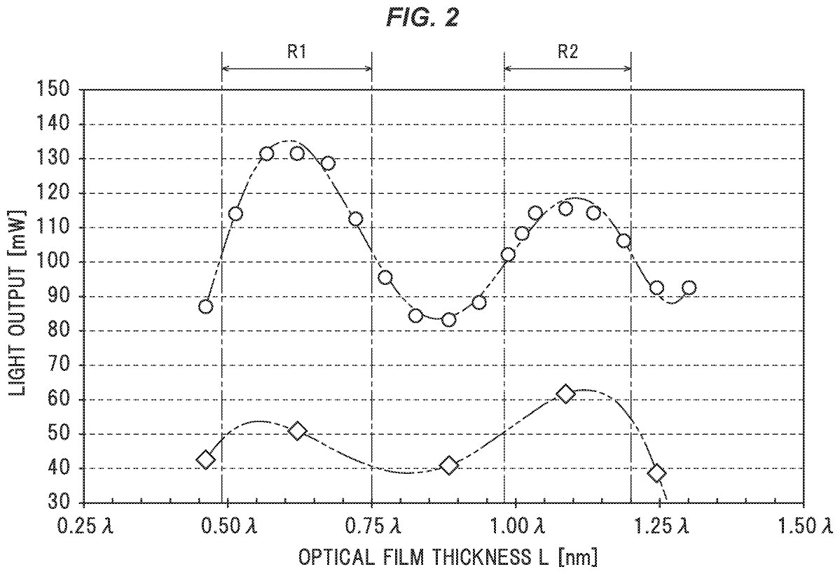

In FIG. 2, a relationship between the optical film thickness L of the second semiconductor layer 5 and the initial light output is plotted by circles, and a relationship between the optical film thickness L of the second semiconductor layer 5 and the residual light output is plotted by diamonds. For reference, an approximate curve fitting the plotted circles and an approximate curve fitting the plotted diamonds are also indicated by dash-dot-dot lines.

Firstly, the results of the initial light output will be described. As shown by the circles plotted in the graph of FIG. 2, local maximum and local minimum of the initial light output repeatedly appear as the optical film thickness L of the second semiconductor layer 5 increases. Here, in the graph of FIG. 2, two peaks of the initial light output appear on left and right sides and the peak located on the left side (i.e., on the side with the smaller optical film thickness L) is larger than the peak located on the right side (i.e., on the side with the larger optical film thickness L). Then, high initial light output of not less than 100 mW is obtained in a first film thickness range R1 which is a relatively wide range of the optical film thickness L of not less than 0.48 λ and not more than 0.75 λ, and in a second film thickness range R2 which is a relatively narrow range of the optical film thickness L of not less than 0.96 λ and not more than 1.20 λ. The first film thickness range R1 and the second film thickness range R2, which are the ranges of the optical film thickness L in which high initial light output is obtained, can be integrated into an inequation 0.48 m λ≤L≤0.5 m λ+(−0.05 m λ+0.3)λ, where the value m is an arbitrary number between 1 and 2. In other words, high initial light output is obtained when the optical film thickness L satisfies 0.48 m λ≤L≤0.5 m λ+(−0.05 m λ+0.3)λ. It is more preferable that the optical film thickness L satisfy the relationship 0.50 m λ≤L≤0.5 m λ+(−0.05 m λ+0.3)λ.

Also as seen in FIG. 2, significantly high initial light output is obtained when the optical film thickness L is not less than 0.55 λ and not more than 0.70 λ in the first film thickness range RE In addition, as seen in FIG. 2, high initial light output is obtained in the second film thickness range R2 when the optical film thickness L is not less than 1.02 λ and not more than 1.15 λ in the second film thickness range R2.

Next, the results of the residual light output will be described. As shown by the diamonds plotted in the graph of FIG. 2, local maximum and local minimum of the residual light output repeatedly appear as the optical film thickness L of the second semiconductor layer 5 increases. In addition, as seen in FIG. 2, high residual light output is obtained when the optical film thickness L satisfies 0.48 m λ≤L≤0.5 m λ+(−0.05 m λ+0.3)λ in the same manner as the initial light output. Furthermore, as seen in FIG. 2, higher residual light output is obtained when the optical film thickness L of the second semiconductor layer 5 is in the second film thickness range R2 than when the optical film thickness L is in first film thickness range RE That is, a decrease in light output of the light-emitting element 1 over time is likely to be suppressed by setting the optical film thickness L within the second film thickness range R2.

### Experimental Example 2

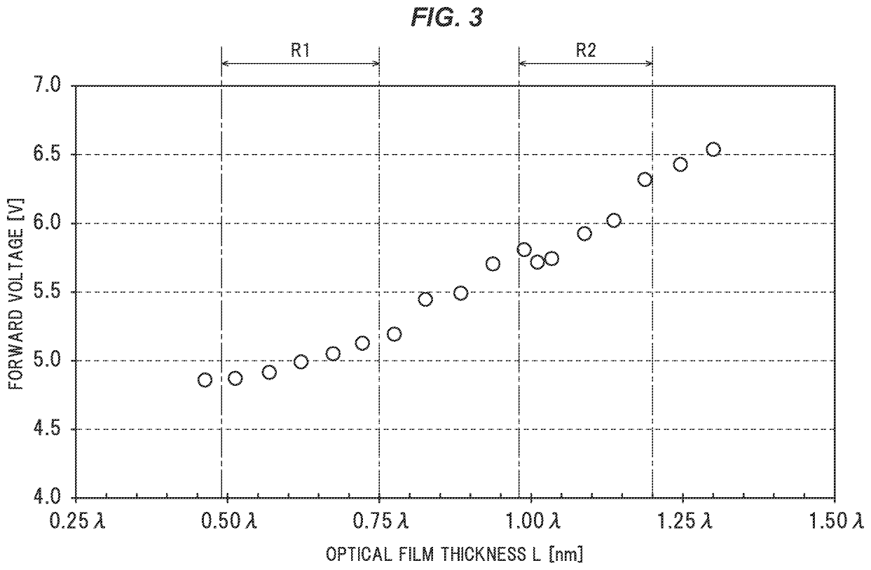

In this experimental example, forward voltage of each of the samples 1 to 18 used in Experimental Example 1 was measured. The results are shown in FIG. 3. As seen in FIG. 3, forward voltage decreases as the optical film thickness L of the second semiconductor layers 5 decreases. Considering the results of this experimental example and the results of Example 1 in FIG. 2, by setting the optical film thickness L of the second semiconductor layer 5 within the first film thickness range R1, it is possible to reduce forward voltage while ensuring sufficient initial light output and residual light output.

(Functions and Effects of the Embodiment)

In the nitride semiconductor light-emitting element 1 of the present embodiment, the p-side reflective electrode 7 is provided so as to be in contact with the second semiconductor layer 5. The relationship 0.48 m λ≤L≤0.5 m λ+(−0.05 m λ+0.3)λ is satisfied in such a configuration, where the optical film thickness of the second semiconductor layer 5 is the optical film thickness L [nm], the central wavelength of the light emitted from the active layer 4 is the wavelength λ [nm], and an arbitrary number between 1 and 2 is the value m. This inequation is an inequation that represents the first film thickness range R1, which is a relatively wide range of the optical film thickness L of not less than 0.48 λ and not more than 0.75 λ and the second film thickness range R2, which is a relatively narrow range of the optical film thickness L of not less than 0.96 λ and not more than 1.20 λ. By satisfying this inequation, high initial light output and high residual light output are obtained as shown by the circles and diamonds plotted in FIG. 2. This is because the reflected emission light EL2 and the direct emission light EL1 interfere with one another to strengthen each other due to the second semiconductor layer 5 which satisfies the above inequation.

In addition, the value m in the inequation 0.48 m λ≤L≤0.5 m λ+(−0.05 m λ+0.3)λ satisfied by the optical film thickness L can be 1. That is, the optical film thickness L of the second semiconductor layers 5 can be an optical film thickness falling within the first film thickness range R1 (i.e., the range of not less than 0.48 λ and not more than 0.75 λ). As a result, higher initial light output is obtained, as shown by the circles plotted in FIG. 2. In addition, since the first film thickness range R1 is a wider range than the second film thickness range R2, it is easy to make the optical film thickness of the second semiconductor layers 5 fall within the first film thickness range R1 at the time of manufacturing, making it easier to manufacture. In addition, it is also possible to reduce the forward voltage, as seen in FIG. 3.

In addition, the optical film thickness L can be set to not less than 0.55 λ and not more than 0.70 λ. In this case, the light-emitting elements 1 can have significantly high initial light output, as shown by the circles plotted in FIG. 2.

In addition, the value m in the inequation 0.48 m λ≤L≤0.5 m λ+(−0.05 m λ+0.3)λ satisfied by the optical film thickness L can be 2. That is, the optical film thickness L of the second semiconductor layers 5 can be within the second film thickness range R2 (i.e., not less than 0.96 λ and not more than 1.20 λ). In this case, significantly high initial light output is obtained among the light-emitting elements 1 having the optical film thicknesses L in the second film thickness range R2, as shown by the circles plotted in the graph of FIG. 2. In addition, as seen in FIG. 2, the residual light output is high in the second film thickness range R2. That is, deterioration in light output over time can be suppressed by setting the optical film thickness L within the second film thickness range R2.

In addition, the optical film thickness L can be set to not less than 1.022 λ and not more than 1.15 λ. In this case, significantly high initial light output is obtained among the light-emitting elements 1 having the optical film thicknesses L in the second film thickness range R2, as shown by the circles plotted in FIG. 2.

In addition, the second semiconductor layer 5 includes the p-type contact layer 53 which is made of p-type GaN and is in contact with the p-side reflective electrode 7, and the thickness of the p-type contact layer 53 is not more than 30 nm. In the present embodiment, the optical film thickness L of the second semiconductor layer 5 is ingeniously designed so that the reflected emission light EL2 and the direct emission light EL1 strengthen each other as described above. However, the p-type contact layer 53 made of p-type GaN tends to absorb light with a short wavelength such as deep ultraviolet light. In addition, if the thickness of the p-type contact layer 53 is more than 30 nm in the present embodiment, the reflected emission light EL2 is likely to be absorbed particularly by the p-type contact layer 53 when traveling up and down in the second semiconductor layer 5, which reduces the effect obtained by ingeniously designing the thickness of the second semiconductor layer 5 so that the reflected emission light EL2 and the direct emission light EL1 strengthen each other. For this reason, the thickness of the p-type contact layer 53 made of p-type GaN is set to not more than 30 nm, resulting in that the reflected emission light EL2 traveling up and down in the second semiconductor layer 5 and then interfering with the direct emission light EL1 can be increased and output of light emitted through the substrate 2 can thereby be further increased.

In addition, the second semiconductor layer 5 has a transmittance of not less than 50% at the central wavelength of the light emitted from the active layer 4. This also results in that the reflected emission light EL2 traveling up and down in the second semiconductor layer 5 and then interfering with the direct emission light EL1 can be increased and output of light emitted through the substrate 2 can thereby be further increased.

In addition, the second p-type cladding layer 522 is configured such that the Al composition ratio decreases toward the p-type contact layer 53. Therefore, it is possible to suppress a sudden change in the Al composition ratio between the layers adjacent to the second p-type cladding layer 522 on the upper and lower sides, i.e., between the p-type contact layer 53 and the first p-type cladding layer 521, and thus possible to suppress occurrence of dislocations caused by lattice mismatch. When dislocations occur in the second semiconductor layer 5, the rate of non-luminescent recombination between electrons and holes in the active later 4 increases and the light emitted from the active layer 4 decreases. However, by providing the second p-type cladding layer 522 as the composition gradient layer as in the present embodiment, it is possible to further improve the light output.

As described above, according to the present embodiment, it is possible to provide a nitride semiconductor light-emitting element capable of improving light output.

(Summary of the Embodiment)

Technical ideas understood from the embodiment will be described below citing the reference signs, etc., used for the embodiment. However, each reference sign, etc., described below is not intended to limit the constituent elements in the claims to the members, etc., specifically described in the embodiment.

[1] The first aspect of the invention is a nitride semiconductor light-emitting element (1), comprising: a first semiconductor layer (3); an active layer (4) provided on the first semiconductor layer (3) on one side; a second semiconductor layer (5) provided on the active layer (4) on the opposite side to the first semiconductor layer (3) so as to be in contact with the active layer (4); and a reflective electrode (7) provided on the second semiconductor layer (5) on the opposite side to the active layer so as to be in contact with the second semiconductor layer (5) and reflects light emitted from the active layer (4), wherein, when an optical film thickness of the second semiconductor layer (5) is an optical film thickness L [nm], a central wavelength of the light emitted from the active layer (4) is a wavelength λ [nm], and an arbitrary number between 1 and 2 is a value m, a relationship 0.48 m λ<L<0.5 m λ+(−0.05 m λ+0.3)λ is satisfied.

With this configuration, it is possible to improve the light output of the nitride semiconductor light-emitting element (1).

[2] The second aspect of the invention is that the value m in the first aspect is 1.

With this configuration, it is possible to improve the initial light output of the nitride semiconductor light-emitting element (1).

It is also possible to improve productivity of the nitride semiconductor light-emitting element (1).

[3] The third aspect of the invention is that the optical film thickness L in the second aspect is not less than 0.55 λ and not more than 0.70 λ.

With this configuration, it is possible to further improve the initial light output of the nitride semiconductor light-emitting element (1).

[4] The fourth aspect of the invention is that the value m in the first aspect is 2.

With this configuration, it is possible to suppress deterioration in the light output of the nitride semiconductor light-emitting element (1) over time.

[5] The fifth aspect of the invention is that the optical film thickness L in the fourth aspect is not less than 1.02 λand not more than 1.15 λ.

With this configuration, it is possible to improve the initial light output of the nitride semiconductor light-emitting element (1).

[6] The sixth aspect of the invention is that the second semiconductor layer (5) in any one of the first to fifth aspects comprises a p-type contact layer (53) comprising p-type GaN and being in contact with the reflective electrode (7), and a thickness of the p-type contact layer (53) is not more than 30 nm.

With this configuration, it is possible to improve the light output of the nitride semiconductor light-emitting element (1).

[7] The seventh aspect of the invention is that the second semiconductor layer (5) in any one of the first to sixth aspects has a transmittance of not less than 50% at the central wavelength.

With this configuration, it is possible to improve the light output of the nitride semiconductor light-emitting element (1).

[8] The eighth aspect of the invention is that the second semiconductor layer (5) in any one of the first to seventh aspects comprises a first p-type cladding layer (521), a second p-type cladding layer (522) and a p-type contact layer (53) sequentially from the active layer (4) side, and the second p-type cladding layer (522) comprises p-type AlGaN and is configured so that an Al composition ratio decreases toward the p-type contact layer (53).

(Additional Note)

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

### REFERENCE SIGNS LIST

1 LIGHT-EMITTING ELEMENT

2 SUBSTRATE

3 FIRST SEMICONDUCTOR LAYER

4 ACTIVE LAYER

5 SECOND SEMICONDUCTOR LAYER

521 FIRST P-TYPE CLADDING LAYER

522 SECOND P-TYPE CLADDING LAYER

53 P-TYPE CONTACT LAYER

7 P-SIDE REFLECTIVE ELECTRODE (REFLECTIVE ELECTRODE)

1. A nitride semiconductor light-emitting element, comprising:
a first semiconductor layer;
an active layer provided on the first semiconductor layer on one side;
a second semiconductor layer provided on the active layer on the opposite side to the first semiconductor layer so as to be in contact with the active layer; and
a reflective electrode provided on the second semiconductor layer on the opposite side to the active layer so as to be in contact with the second semiconductor layer and reflects light emitted from the active layer,
wherein, when an optical film thickness of the second semiconductor layer is an optical film thickness L [nm], a central wavelength of the light emitted from the active layer is a wavelength λ [nm], and an arbitrary number between 1 and 2 is a value m, a relationship 0.48 m λ≤L≤0.5 m λ+(−0.05 m λ+0.3)λ is satisfied.

2. The nitride semiconductor light-emitting element according to claim 1, wherein the value m is 1.

3. The nitride semiconductor light-emitting element according to claim 2, wherein the optical film thickness L is not less than 0.55 λ and not more than 0.70 λ.

4. The nitride semiconductor light-emitting element according to claim 1, wherein the value m is 2.

5. The nitride semiconductor light-emitting element according to claim 4, wherein the optical film thickness L is not less than 1.02 λ and not more than 1.15 λ.

6. The nitride semiconductor light-emitting element according to claim 1, wherein the second semiconductor layer comprises a p-type contact layer comprising p-type GaN and being in contact with the reflective electrode, and wherein a thickness of the p-type contact layer is not more than 30 nm.

7. The nitride semiconductor light-emitting element according to claim 1, wherein the second semiconductor layer has a transmittance of not less than 50% at the central wavelength.

8. The nitride semiconductor light-emitting element according to claim 1, wherein the second semiconductor layer comprises a first p-type cladding layer, a second p-type cladding layer and a p-type contact layer sequentially from the active layer side, and wherein the second p-type cladding layer comprises p-type AlGaN and is configured so that an Al composition ratio decreases toward the p-type contact layer.
